(19) United States
(12) Patent Application Publication
(10) Pub. No.: US 2010/0220866 A1
(43) Pub. Date: Sep. 2, 2010

(54) THIN SPEAKER WITH IMPROVED BASS/DEEP BASS SOUND EFFECT

(76) Inventor: Wei HSU, Chung Ho City (TW)

Correspondence Address: Muncy, Geissler, Olds & Lowe, PLLC, 4000 Legato Road, Suite 310, FAIRFAX, VA, 22033, US

(21) Appl. No.: 12/505,143

(22) Filed: Jul. 17, 2009

(30) Foreign Application Priority Data
Feb. 27, 2009 (TW) 098106580

(51) Int. Cl. H03G 3/00; H04R 1/02

(52) U.S. Cl. 381/61; 381/345

(57) ABSTRACT

The present invention discloses a thin speaker with improved bass/deep bass sound effect, comprising a housing; a thin plate with honeycomb structure inside the housing; at least one voice coil module which comprises at least one audio signal input interface to receive the audio signal inputs from an external device; at least one magnetic module fixed to the back side of the housing, to facilitate the voice coil module to generate corresponding vibrations when receiving audio signal inputs, and the amplitudes of vibrations are amplified by the thin plate to generate sounds; and at least one passive plate set on the back side of the housing for improving the bass/deep bass sound effect. The present invention provides a thin speaker with improved bass/deep bass sound effect.

### FIELD OF THE INVENTION

The present invention is generally related to the field of thin speaker and, more particularly, to a thin speaker with improved bass/deep bass sound effect.

### DESCRIPTION OF THE PRIOR ART

Speakers or loudspeakers are used in a variety of applications. Conventional speakers provide fine sound quality with sound enclosures such as the U.S. Pat. Publication 5,850,460 “Bass Speaker”. It provides a structure of a bass speaker comprising a first driver unit, a second driver unit, a first passive radiator, a second passive radiator, etc. With the huge components such as passive radiators within the big vibration space provided, a powerful output bass sound is thus provided. The prior art provides a powerful output bass sound, but it also provides a bulky physical volume, however. The prior art also provides several shortcomings such as space-wasting, cumbersome or heavy, hard to set or adjust, etc. In addition to the audio/video devices using in the house, the audio/video devices further comprise mobile personal computer (PC), notebook, netbook or Ultra Mobile Personal Computer (UMPC), mobile phone, electronic dictionary, personal digital assistant (PDA), global positioning system (GPS), walkman, mobile gaming device, etc., with the development of technologies. The above-mentioned devices also need speakers with good sound effect, but apparently they may not work well with the conventional speakers.

In contrast, thin speakers may be well suited to the above-mentioned devices, and the thin speakers may greatly save the space occupied by the devices in the house. There are several thin (or planar or flat) speakers, such as ribbon type planar speaker, piezoelectric thin speaker, hanging picture-type flat speaker, etc. The ribbon type planar speaker is characterized by forming the metal conductor directly on the insulator film and thus forming the diaphragm having electronic circuits. The ribbon type planar speaker is credited for reducing the thickness and weight by not connecting a voice coil, but it performs badly on responses at low-frequency sound. The problem of out of synchronization is thus often generated on its film vibration, and its performance is lowered by not generating rigid body piston motion. Therefore, several shortcomings of the ribbon type planar speaker are existed.

On another hand, while piezoelectric thin speakers own several advantages such as thinner in shape and lower in power consumption, they failure to provide high sound quality because of their high sound distortion. Therefore, they are almost applied in low-end audio products such as alarm devices, small toys, etc. Nowadays they are not good substitutes for conventional bulky speakers.

On another hand, hanging picture-type flat speakers are bothered by the problem of frequency shifting generated by the sound reflection from their backward walls. Although prior art provides an energy dissipating device having sound absorption material for setting between the vibrator and wall and overcoming the problem of sound reflection, but the energy dissipating device increases the weight and has not further purposes. Furthermore, the energy dissipating device does not improve the low-frequency sound effect.

Therefore, the present invention discloses a thin speaker with improved bass/deep bass sound effect. The thin speaker not only reduces the weight and volume but also amends the shortcomings of above-mentioned several speakers.

### SUMMARY OF THE INVENTION

In a first aspect of the present invention, a thin speaker is provided.

In another aspect of the present invention, a thin speaker with improved bass/deep bass sound effect is provided.

The thin speaker of the present invention comprises a housing; a thin plate with honeycomb structure inside the housing; at least one voice coil module which comprises at least one audio signal input interface to receive the audio signal inputs from an external device; at least one magnetic module fixed to the back side of the housing, to facilitate the voice coil module to generate corresponding vibrations when receiving audio signal inputs, and the amplitudes of vibrations are amplified by the thin plate to generate sounds; and at least one passive plate set on the back side of the housing for improving the bass/deep bass sound effect. The present invention is characterized by making the speaker thinner and owning improved bass/deep bass sound effect at the same time.

### BRIEF DESCRIPTION OF THE DRAWINGS

FIG. 1 illustrates the thin speaker with improved bass/deep bass sound effect according to the embodiments of the present invention.

### DESCRIPTION OF THE PREFERRED EMBODIMENT

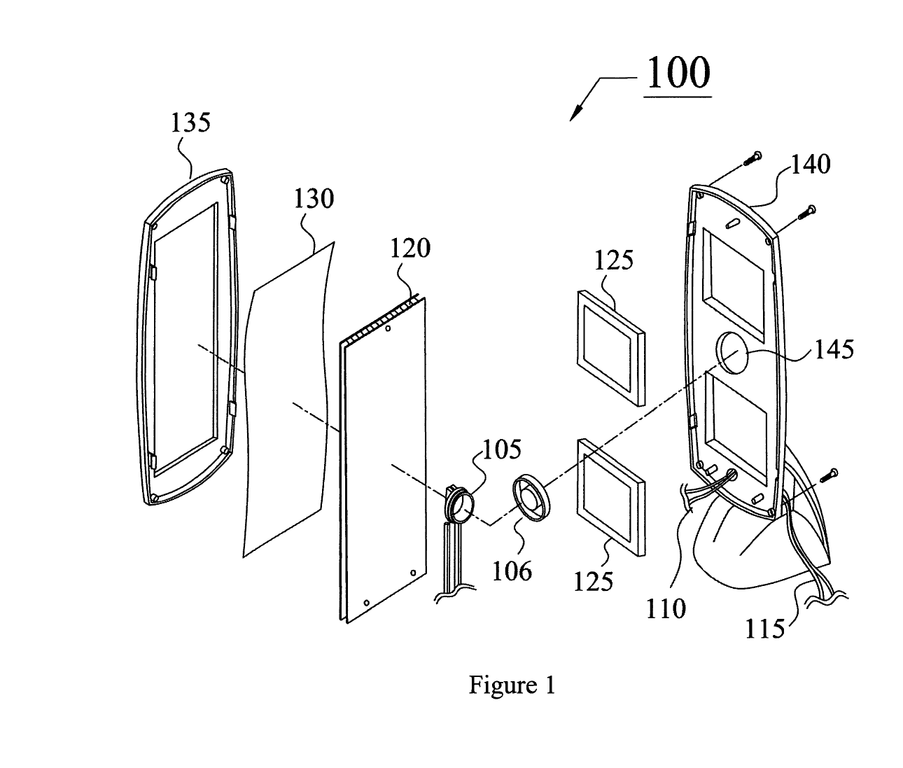

FIG. 1 illustrates the thin speaker with improved bass/deep bass sound effect according to the embodiments of the present invention. As illustrated, the thin speaker 100 comprises a housing which comprises the front housing 135 and back housing 140, formed separately or integrally, for containing the following elements; a voice coil module 105, connecting to a audio signal input line 110 and an audio signal input interface 115 to receive audio signal inputs from an external device; a thin plate structure 120 with honeycomb structure connecting to the voice coil module 105 (for example, they can be connected by adhension); a magnetic module 106 fixed to the back housing 140 via a magnetic module placing structure 145, and the magnetic module 106 is jointed with the voice coil module 105 (the voice coil module 105 is not fixed to the magnetic module 106, the voice coil module 105 can be moved relative to the magnetic module 106); wherein the magnetic module 106 having magnetic field itself, and it can be made of a permanent magnet. When the coil module 105 receives audio signal input current with different intensities (frequencies) via audio signal input line 110, the coil module 105 generates corresponding magnetic field with different intensities (frequencies). In a compact space, the time-varying magnetic field of the voice coil module 105 is repelled or attracted by the magnetic module 106 fixed to the back housing 140, and thus the vibration of the voice coil module 105 is generated. Because the voice coil module 105 is fixed to the thin plate structure 120, the thin plate structure 120 then vibrates and generates sound. The thin plate structure 120 amplifies the effect of the vibration of the voice coil module 105 to generate sound with audible amplitude, and the materials of the thin plate structure 120 comprise but not limit to paper, plastic, fiber, leather, etc., wherein fiber further comprises animal fiber, vegetable fiber, regenerated fiber, artificial fiber, etc. According to the embodiments of the present invention, the thin speaker 100 further comprises a set of passive plates 125 (two passive plates in the illustration) which are inserted into the back housing 140. As illustrated, each of the two passive plates 125 comprises a thin and rigid material, such as thin and rigid plastic plate, in the center area and an elastic material, such as elastic rubber, around the rigid material. The passive plates 125 can vibrate relative to the back housing 140 for improving the effect (quality) of low-frequency sound generated by the thin plate structure 120, i.e., the bass/deep bass sound effect is improved. The thin speaker further comprises a protection component 130, to prevent dust, resist moisture, and/or protect inter components. Furthermore, the front housing 135 and back housing 140 covering the inter components also provide effect of protection.

As illustrated, several components within the thin speaker 100 are formed in shape of thin plate and assembled in a limited space by precise processes. The present invention is characterized by providing improved (bass/deep bass) sound effect in a space almost limited to two-dimensional condition. It should be noted that although the voice coil module 105 is set on the position of the geometric center of the thin speaker 100 in the illustration, the voice coil module 105 is not limited to be set on this position. Considering of the different materials, shapes, thickness, etc., the distribution of the vibrational normal modes of the thin plate structure 120 is not the same. Accordingly, for preferred vibrational effect (sound effect), the voice coil module 105 can be set on the position of vibrational maximums or kept away from the vibrational nodes or nodal lines. Further, the number of voice coil module 105 is not limit to one. A plurality of identical or non-identical voice coil module can be implemented for better sound effect, such as stereo or surrounding effect. Using different voice coil modules with different coil sizes or different winding ways, voice coil modules with different optimal sound effects can be applied together. The shape, size, number, etc. of the magnetic module 106 is corresponding to the voice coil module. In other words, the number of the magnetic module 106 is the same with the number of the voice coil module. The magnetic module 106 is fixed to the back housing 140, and the position of the magnetic module is corresponding to the voice coil module 105.

The present invention is further characterized by implementation of the passive plates 125. The shape, number, thickness, position, etc. of the passive plates 125 are not limited to the illustration. They can be adjusted for different purposes. As illustrated in FIG. 1, the passive plates 125 are set in back of the voice coil module 105. In fact, the passive plates 125 can be set in front of the voice coil module 105 in other embodiments of the present invention. In the preferred embodiment, the passive plates are set in back of the voice coil module 105. The thickness, size, and shape of the passive plates 125 can also be adjusted. For decreasing the overall weight of the thin speaker 100, the positions of the vibrational normal modes, such as vibrational nodes or nodal lines, of the thin plate structure 120 or passive plates 125 can be thinned down or excavation. By this way, the manufacturing cost of the thin speaker 100 is thus reduced, and the weight or volume of it is also reduced. In addition to improving the bass/deep bass sound effect of the thin speaker 100, the implementation of the passive plates 125 can also strengthen the rigidity and reduce the problem of sound reflection.

Further, the audio signal input interface 115 is implemented as a wire interface as in illustration. In fact, in other embodiments of the present invention, it can also be implemented as a wireless interface. Furthermore, the audio signal input interface 115 may also comprise digital signal input interface, analog signal input interface, etc. It further comprises but not limit to universal serial bus (USB), mini universal serial bus (Mini USB), Audio/Video (AV) input interface, component AV input interface, high definition multimedia interface (HDMI), RCA audio input interface, coaxial cable input interface, fiber input interface, infrared interface, Bluetooth interface, etc. For receiving and decoding the multiple audio signal inputs with the multiple audio signal input interfaces, a chip, processor, microprocessor, etc. is set within or without the thin speaker.

In the detailed description and illustration above, for the purposes of explanation, numerous specific details are set forth for providing a thorough understanding of the present invention but not for limiting the scope of the present invention to a specific detail. In other embodiments of the present invention, the dimension, ratio, and using of the components are not necessarily the same with the illustration. In fact, the skills in art should appreciate that certain components in the description may not be necessary when implementing the present invention, and the layout in the illustration is not the only way as well. For purposes of clarity and brevity, certain conventional components, such as assembling components, audio volume adjusting component, etc., are neglected without giving description or illustration. Further modifications or variations can be made upon the teachings of the embodiments of the present invention for further application in different conditions. Therefore, the spirit and scope of the present invention should not be limit to a specific way or detail disclosed by the present invention. The spirit and scope of the present invention should be defined by the following claims, and any modifications and variations without departing from the spirit and scope of the present invention should be included.

What is claimed is:

1. A thin speaker with improved bass/deep bass sound effect, comprising:
a housing;
at least one thin plate structure set inside front side of said housing;
at least one voice coil module fixed to said at least one thin plate structure and comprising at least one audio signal input interface for receiving audio signal inputs from an external device;
at least one magnetic module set inside back side of said housing for facilitating said at least one voice coil module to generate vibrations when said at least one voice coil module receives said audio signal inputs and generates magnetic fields, wherein said vibrations are generated by repulsion and attraction forces between said voice coil module and said magnetic module, and said vibrations are amplified by said thin plate structure for generating sound; and
at least one passive plate inserted into said back side of said housing for improving low-frequency sound effect of said sound.

2. The thin speaker with improved bass/deep bass sound effect of claim 1, further comprising a magnetic module placing structure set on said back side of said housing for fixing said magnetic module to said back side of said housing.

3. The thin speaker with improved bass/deep bass sound effect of claim 1, wherein center area of said at least one passive plate is made of thin and rigid material, and an elastic material is formed around said thin and rigid material.

4. The thin speaker with improved bass/deep bass sound effect of claim 1, wherein said thin plate structure is made of hollow structure.

5. The thin speaker with improved bass/deep bass sound effect of claim 1, wherein said thin plate structure is made of honeycomb structure.

6. The thin speaker with improved bass/deep bass sound effect of claim 1, wherein material of said thin plate structure comprising animal fiber, vegetable fiber, regenerated fiber, artificial fiber, or combinations thereof.

7. The thin speaker with improved bass/deep bass sound effect of claim 1, wherein material of said thin plate structure comprising plastic.

8. The thin speaker with improved bass/deep bass sound effect of claim 1, wherein material of said thin plate structure comprising leather.

9. The thin speaker with improved bass/deep bass sound effect of claim 1, further comprising a plurality of said thin speakers for using in series connection, parallel connection, or combinations thereof.

10. The thin speaker with improved bass/deep bass sound effect of claim 1, wherein said audio signal input interface comprises wire interface, wireless interface, or combinations thereof.

11. The thin speaker with improved bass/deep bass sound effect of claim 1, wherein said audio signal input interface comprises digital signal input interface, analog signal input interface, or combinations thereof.

12. The thin speaker with improved bass/deep bass sound effect of claim 1, wherein said audio signal input interface comprises universal serial bus (USB), mini universal serial bus (Mini USB), Audio/Video (AV) input interface, component AV input interface, high definition multimedia interface (HDMI), RCA audio input interface, coaxial cable input interface, fiber input interface, infrared interface, Bluetooth interface, or combinations thereof.

13. The thin speaker with improved bass/deep bass sound effect of claim 1, further comprising at least one chip, processor, microprocessor, or a combination thereof, to couple with said audio signal input interface.
